(19) United States
(12) Patent Application Publication
(10) Pub. No.: US 2009/0231979 A1
(43) Pub. Date: Sep. 17, 2009

(54) OPTICAL RECORDING MEDIUM

(75) Inventors: Rumiko HAYASE, Yokohama-shi (JP); Kazuki Matsumoto, Kawasaki-shi (JP); Satoshi Mikoshiba, Yamato-shi (JP); Norikatsu Sasao, Tokyo (JP); Takahiro Kamikawa, Kawasaki-shi (JP); Masahiro Kanamaru, Fuchu-shi (JP); Masaya Terai, Fuchu-shi (JP)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: Kabushiki Kaisha Toshiba

(21) Appl. No.: 12/369,548

(22) Filed: Feb. 11, 2009

(30) Foreign Application Priority Data
Mar. 13, 2008 (JP) 2008-064239

(51) Int. Cl. G11B 7/00; G03F 7/00

(52) U.S. Cl. 369/103; 430/2

(57) ABSTRACT

An optical recording medium is provided, which includes a recording layer includes a polymer matrix, a polymerizable compound, a photopolymerization initiator, and a polymerization inhibitor. The polymerization inhibitor is formed of a compound which exhibits a molar absorption coefficient of zero to a light having a first wavelength and generates an acid or a base when exposed to an external stimulus other than the light having the first wavelength, thereby inhibiting the polymerization of the polymerizable compound.

### CROSS-REFERENCE TO RELATED APPLICATIONS

This application is based upon and claims the benefit of priority from prior Japanese Patent Application No. 2008-064239, filed Mar. 13, 2008, the entire contents of which are incorporated herein by reference.

### BACKGROUND OF THE INVENTION

1. Field of the Invention

This invention relates to an optical recording medium, to an optical recording method and to an optical information recording/reading apparatus.

2. Description of the Related Art

A hologram recording medium can be manufactured by a method wherein a photopolymer comprising, as major components, a photopolymerizable monomer, a matrix resin, a photopolymerization initiator and a sensitizing dye, for example, is molded into a film. In this recording medium, since the polymerization of the photopolymerizable monomer is accelerated at a portion which is strongly irradiated by light, information can be recorded through interference exposure. Namely, when the polymerization of the photopolymerizable monomer takes place, the photopolymerizable monomer diffuses from a portion where the light is weakly irradiated into a portion where the light is strongly irradiated, thereby creating a concentration gradient.

In conformity with the degree of intensity of interference light, a difference in density of photopolymerizable monomer is generated, thus creating a difference in refractive index. If an unreacted photopolymerizable monomer or a photopolymerization initiator remain in a recording layer after the recording of information, the diffusion or reaction of these materials takes place with time as the recording layer receives thermal stimulus or light. As a result, it may become difficult to accurately read out the information recorded in the recording layer. In order to avoid these problems, it has been practiced to irradiate light to the recording layer after the recording of information, thereby consuming the unreacted monomer or the photopolymerization initiator and fixing the information.

In order to enable the monomer and the photopolymerization initiator to be entirely polymerized through the irradiation of light, it is necessary to irradiate the light for a long period of time, resulting in the prolongation of the recording time. Further, since the volume of the recording medium contracts in volume due to the polymerization of the monomer, it may become difficult to accurately read out the recorded information. When the unreacted monomer is polymerized, the difference in refractive index that has been created at the bright and dark portions of interference fringes may be reduced, thus possibly resulting in the deterioration of the recorded images.

A method of solving the aforementioned problems has been proposed in JP-A 2007-86196 (KOKAI), wherein a compound having an ethylenic double bond such as an unreacted α,β-unsaturated acrylic monomer is reacted with amine or mercaptan by a Michael addition reaction, thereby avoiding the polymerization of the unreacted monomer.

### BRIEF SUMMARY OF THE INVENTION

An optical recording medium according to one aspect of the present invention comprises a recording layer comprising a polymer matrix, a polymerizable compound, a photopolymerization initiator, and a polymerization inhibitor, the polymerization inhibitor being formed of a compound which exhibits a molar absorption coefficient of zero to a light having a first wavelength and generates an acid or a base when exposed to an external stimulus other than the light having the first wavelength.

A method for optical recording according to one aspect of the present invention comprises:

irradiating a first light having a first wavelength which can be absorbed by the photopolymerization initiator to the aforementioned optical recording medium; and

irradiating a second light having a second wavelength which differs in wavelength from the first wavelength and which can be absorbed by the photopolymerization initiator.

An information recording/reading apparatus according to a further aspect of the present invention comprises: a light source; an optical element for rotatory polarization; a beam splitter; a mirror; and a detector; wherein the apparatus is designed to read out and regenerate information from recorded portions of the aforementioned optical recording medium.

### BRIEF DESCRIPTION OF THE SEVERAL VIEWS OF THE DRAWING

FIG. 1 is a cross-sectional view schematically illustrating a transmission type holographic optical recording medium according to one embodiment;

FIG. 2 is a cross-sectional view schematically illustrating a reflection type holographic optical recording medium according to another embodiment;

FIG. 3 is a diagram schematically illustrating a transmission type optical recording/regeneration apparatus according to a further embodiment;

FIG. 4 is a diagram schematically illustrating a reflection type optical recording/regeneration apparatus according to a further embodiment;

FIG. 5 is a diagram illustrating a pattern of recording light; and

FIG. 6 is a diagram illustrating a pattern of reference light to be employed on the occasion of reading information.

### DETAILED DESCRIPTION OF THE INVENTION

Next, embodiments will be explained.

The recording layer of an optical recording medium according to one embodiment comprises a polymer matrix, a polymerizable compound, a photopolymerization initiator, and a polymerization inhibitor. The photopolymerization initiator is formed of a compound which initiates the polymerization of a polymerizable compound when irradiated with a recording light. The polymerization inhibitor is formed of a compound which exhibits a molar extinction coefficient of zero to this recording light and is substantially incapable of absorbing this recording light. Furthermore, the compound constituting this polymerization inhibitor generates an acid or a base when exposed to an external stimulus other than the recording light, thereby inhibiting the polymerization of the polymerizable compound.

As the polymer matrix, it is possible to employ, for example, thermoplastic resins, epoxy resin, urethane resin, etc.

With respect to the polymerizable compound, it may be selected from a radical polymerizable monomer, a cationic polymerizable monomer, and an anionic polymerizable monomer.

As examples of the radical polymerizable monomer, they include a compound having an ethylenic unsaturated double bond, examples of which include, for example, unsaturated carboxylic acid, unsaturated carboxylate, unsaturated carboxylic acid amide, and vinyl compounds.

More specifically, specific examples of the radical polymerizable monomer include acrylic acid, methyl acrylate, ethyl acrylate, propyl acrylate, butyl acrylate, isobutyl acrylate, 2-ethylhexyl acrylate, octyl acrylate, lauryl acrylate, stearyl acrylate, cyclohexyl acrylate, bicyclopentenyl acrylate, phenyl acrylate, isobonyl acrylate, adamantyl acrylate, methacrylic acid, methyl methacrylate, propyl methacrylate, butyl methacrylate, phenyl methacrylate, phenoxyethyl acrylate, chlorophenyl acrylate, naphthyl acrylate, naphthyl methacrylate, adamantyl methacrylate, isobonyl methacrylate, N-methyl acrylic amide, N,N-dimethyl acrylic amide, N,N-dimethyl aminopropyl acrylic amide, N,N-dimethyl aminoethyl acrylate, 2,4,6-tribromophenyl acrylate, 2,3,4,5,6-pentabromophenyl acrylate, styrene, bromostyrene, chlorostyrene, vinyl naphthalene, vinyl naphthoate, N-vinyl pyrrolidinone, N-vinyl carbazole, polyethylene glycol diacrylate, polyethylene glycol dimethacrylate, tripropylene glycol diacrylate, propylene glycol trimethacrylate, diallyl phthalate, triallyl trimellitate, etc.

With respect to examples of the cationic polymerizable monomer, they include, for example, epoxy compounds, oxetane compounds, vinyl ether compounds, etc.

With respect to specific examples of the epoxy compound, they include, for example, butanediol diglycidyl ether, diepoxy octane, hexanediol diglycidyl ether, ethylhexyl glycidyl ether, isobutyl glycidyl ether, phenyl glycidyl ether, naphthyl glycidyl ether, glycidyl benzoate, hydroquinone diglycidyl ether, glycidyl phthalimide, polyethylene glycol diglycidyl ether, polypropylene glycol diglycidyl ether, resorcinol diglycidyl ether, neopentyl glycol diglycidyl ether, bisphenol A diglycidyl ether, bisphenol F diglycidyl ether, diglycidyl ether of biphenyl ether and derivatives thereof, tetraglycidyl diether of 2,2′,4,4′-tetrahydroxy benzophenone, N,N-diglycidylaminoglycidoxy benzene, 1,3,5-triglycidoxy benzene, 2,2′,4,4′-tetraglycydoxy biphenyl, 4,4′-bis(2,3-epoxypropoxy)-3,3′,5,5′-tetramethyl biphenyl, N,N,N′,N′-tetraglycidyl aminodiphenyl methane, dicyclopentadiene type epoxy resin, 3,4-epoxycyclohexenylmethyl-3′,4′-epoxycyclohexene carboxylate, epoxypropoxypropyl-terminated polydimethyl siloxane, various kinds of epoxy halide compounds, etc.

With respect to specific examples of the oxetane compound, they include, for example, 3-ethyl-3-hydroxymethyl oxetane (Toagousei Co., Ltd.), 1,4-bis{[(3-ethyl-3-oxetanyl)methoxy]methyl}benzene, di[1-ethyl(3-oxetanyl)]methyl ether, 3-ethyl-3-(2-ethylhexyloxymethyl)oxetane, 3-ethyl-3-(phenoxymethyloxy)oxetane, oxetanylsilsesquioxetane, phenol novolac oxetane, 1,3-bis[(l-ethyl-3-oxetanyl)methoxy]benzene, 4,4′- bis[(3-ethyl-3-oxetanyl)methoxy]biphenyl, etc.

With respect to specific examples of the vinyl ether compound, they include, for example, n-propylvinyl ether, n-butylvinyl ether, isobutylvinyl ether, tert-butylvinyl ether, tert-amylvinyl ether, cyclohexylvinyl ether, 2-ethylhexylvinyl ether, dodecylvinyl ether, octadecylvinyl ether, 2-chloroethylvinyl ether, ethylene glycol butylvinyl ether, triethylene glycol methylvinyl ether, ethylene glycol divinyl ether, diethylene glycol divinyl ether, triethylene glycol divinyl ether, tetraethylene glycol divinyl ether, butane-1,4-diol-divinyl ether, hexane-1,6-diol-divinyl ether, (4-vinyloxy)butyl benzoate, cyclohexane-1,4-dimethanol-divinyl ether, di(4-vinyloxy)butyl isophthalate, succinic acid di(4-vinyloxy)butyltrimethylol propanetrivinyl ether, di(4-vinyloxy)butyl glutarate, 2-hydroxyethylvinyl ether, 4-hydroxybutylvinyl ether, 6-hydroxyhexylvinyl ether, cyclohexane-1,4-dimethanol-monovinyl ether, diethylene glycol monovinyl ether, 3-aminopropylvinyl ether, 2-(N,N-diethylamino)ethylvinyl ether, polyester vinyl ether, urethanevinyl ether, etc.

With respect to specific examples of the anionic polymerizable monomer, they include unsaturated carboxylate, unsaturated carboxylic acid amide, unsaturated cyanocarboxylate, styrene, etc.

More specifically, specific examples thereof include, for example, acrylic acid, methyl acrylate, ethyl acrylate, propyl acrylate, butyl acrylate, isobutyl acrylate, 2-ethylhexyl acrylate, octyl acrylate, lauryl acrylate, stearyl acrylate, cyclohexyl acrylate, bicyclopentenyl acrylate, phenyl acrylate, isobonyl acrylate, adamantyl acrylate, methacrylic acid, methyl methacrylate, propyl methacrylate, butyl methacrylate, phenyl methacrylate, phenoxyethyl acrylate, chlorophenyl acrylate, naphthyl acrylate, naphthyl methacrylate, adamantyl methacrylate, isobonyl methacrylate, N-methyl acrylic amide, N,N-dimethyl acrylic amide, N,N-dimethyl aminopropyl acrylic amide, N,N-dimethyl aminoethyl acrylate, 2,4,6-tribromophenyl acrylate, 2,3,4,5,6-pentabromophenyl acrylate, etc.

The aforementioned polymerizable compounds are preferably incorporated in the recording layer at an amount ranging from 1 to 50% by weight based on a total weight of the recording layer. If the amount of these polymerizable compounds is less than 1% by weight, it may become impossible to sufficiently increase the refractive index of the recording region. On the other hand, if the amount thereof exceeds 50% by weight, the contraction of volume may become too large, thus possibly deteriorating the resolution. More preferably, the amount of these polymerizable compounds should be confined to 3 to 30% by weight based on a total weight of the recording layer.

The photopolymerization initiator may be selected depending on the kind of the polymerizable compound. For example, it is possible to employ a radical photopolymerization initiator, a cationic photopolymerization initiator, and an anionic photopolymerization initiator.

As examples of the radical photopolymerization initiator, they include, for example, imidazole derivatives, organic azide compounds, titanocenes, organic peroxides, thioxanthone derivatives, etc. More specifically, it is possible to employ the following compounds. Namely, they include benzyl, benzoin, benzoin ethyl ether, benzoin isopropyl ether, benzoin butyl ether, benzoin isobutyl ether, 1-hydroxycyclohexyl phenyl ketone, benzyl methyl ketal, benzyl ethyl ketal, benzyl methoxyethyl ether, 2,2′-diethylacetophenone, 2,2′-dipropylacetophenone, 2-hydroxy-2-methylpropiophenone, p-tert-butyltrichloroacetophenone, thioxanthone, 2-chlorothioxanthone, 2-isopropylthioxanthone, 4-isopropylthioxanthone, 2-methyltioxanthone, 3,3′,4,4′-tetra(t-butyl peroxycarbonyl)benzophenone, 2,4,6-tris(trichloromethyl)1,3,5-triazine, 2-(p-methoxyphenyl)-4,6-bis(trichloromethyl)1,3,5-triazine, 2-[(p-methoxyphenyl)ethylene]-4,6-bis(trichloromethyl)1,3,5-triazine, Irgacure 149, 184, 369, 651, 784, 819, 907, 1700, 1800, 1850 (Ciba Japan K.K.), di-t-butyl peroxide, dicumyl peroxide, t-butylcumyl peroxide, t-butyl peroxyacetate, t-butyl peroxyphthalate, t-butyl peroxybenzoate, acetyl peroxide, isobutyryl peroxide, decanoyl peroxide, lauroyl peroxide, benzoyl peroxide, t-butyl hydroperoxide, cumene hydroperoxide, methylethyl ketone peroxide, cyclohexanone peroxide, etc.

With respect to specific examples of the cationic photopolymerization initiator, they include, for example, onium salts, diazonium salts, phosphonium salts, sulfonium salts, and iodonium salts of CF₃SO₃—, p-CH₃PhSO₃— and p-NO₂PhSO₃—; triazines, etc. More specifically, they include di(paratertiary butylphenyl)iodonium trifluoromethane sulfonate, di(paratertiary butylphenyl)iodonium tetrafluoroborate, di(paratertiary butylphenyl)iodonium tetrafluoroarsenate, di(paratertiary butylphenyl)iodonium tetrafluoroantimonate, benzointosylate, orthonitrobenzyl paratoluene sulfonate, triphenyl sulfonium trifluoromethane sulfonate, tri(tertiary butylphenyl)sulfonium trifluoromethane sulfonate, benzene diazonium paratoluene sulfonate, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2,4-bis(trichloromethyl)-6-(p-methoxyphenylvinyl)-1,3,5-triazine, 2-(4′-methoxy-1′-naphthyl)-4,6-bis(trichloromethyl)-1,3,5-triazine, etc.

Specific examples of the anionic photopolymerization initiator include, for example, nitrobenzyl carbamate compounds such as [(orthonitrobenzyl)oxy]carbonyl cyclohexyl amine, etc.; photo-functional urethane compounds such as N-[[1-(3,5-dimethoxyphenyl)-1-methyl-ethoxy]carbonyl]cyclohexyl amine, N-[[1-(3,5-dimethoxyphenyl)-1-methyl-ethoxy]carbonyl]pyridine, etc.

These polymerization initiators should preferably be incorporated in the recording layer at an amount ranging from 0.05 to 20% by weight based on a total weight of the recording layer. If the amount of these polymerization initiators is less than 0.05% by weight, it may become impossible to obtain a sufficient change in refractive index. On the other hand, if the amount of these polymerization initiators exceeds 20% by weight, the light absorption by the recording layer would become too large, thus possibly deteriorating the resolution. More preferably, the amount of the polymerization initiator should be confined to 0.1 to 10% by weight based on a total weight of the recording layer.

A mixture comprising the polymer matrix, polymerizable compound and the photopolymerization initiator described above is referred to herein as a photopolymer. It may be said that this photopolymer contains a compound (polymerizable compound) which brings about the modulation of refractive index through the polymerization reaction thereof such as cationic polymerization, anionic polymerization, radical polymerization, etc.

The recording layer in the optical recording medium according to one embodiment can be formed using such photopolymer. When the recording layer is irradiated with a recording light, the polymerizable compound is caused to polymerize, to generate the modulation of refractive index in the exposure region of the recording layer, thus executing the recording of information. However, an unreacted polymerizable compound remains in the recording layer. In order to fix the recorded information, there has been conventionally adopted a method wherein the irradiation of light is continued for a long period of time after finishing the recording, to consume the residual polymerizable compound.

In the embodiments however, the fixing of information is performed by a compound (polymerization inhibitor) which inhibits the polymerization of the polymerizable compound. As the polymerization inhibitor in this case, it is possible to employ a compound which exhibits zero absorbency of the recording light as measured using a dilute solution where the Lambert-Beer Law can be made valid. Since the compound of this kind is incapable or hardly capable of absorbing the recording light, there is no possibility of generating an acid or a base. Even if an acid or a base generate by the irradiation of the recording light, the quantity thereof would be extremely limited, so that it would be impossible to inhibit the polymerization reaction of the polymerizable compound on the occasion of executing the recording of information.

Additionally, the compound to be used as a polymerization inhibitor generates an acid or a base when exposed to an external stimulus which differs from the recording light. With respect to the external stimulus, it is possible to employ a light exhibiting a wavelength which differs from that of the recording light or to employ heating. The compound which is substantially incapable of absorbing the recording light and generats an acid or a base when exposed to a light having a different wavelength from that of the recording light can be selected from the cationic photopolymerization initiators and the anionic photopolymerization initiators described above.

With respect to specific examples of the compound which generates an acid when exposed to heat, it is possible to employ a compound which is known as a cationic polymerization catalyst. For example, it may be selected from the group consisting of Lewis acid containing any one of materials including BF₃, SnCl₄, TiCl₄, AlEtCl₂, ZnCl₂, FeCl₃ and AlCl₃; and onium salts such as diazonium salts, phosphonium salts, sulfonium salts and iodonium salts. In view of the storage stability of the optical recording medium, onium salts is more preferable.

With respect to specific examples of the compound which generates a base when exposed to heat, it is possible to employ aforementioned nitrobenzyl carbamate compounds such as [(orthonitrobenzyl)oxy]carbonyl cyclohexyl amine; N-[[1-(3,5-dimethoxyphenyl)-1-methyl-ethoxy]carbonyl]cyclohexyl amine; and N-[[1-(3,5-dimethoxyphenyl)-1-methyl-ethoxy]carbonyl]pyridine.

For the purpose of minimizing the warpage of the recording medium as well as for the purpose of preventing the turbulence of the recorded portion, it is more preferable to employ a light having a different wavelength from that of the recording light in the step of fixing treatment.

In the case of the photopolymer wherein the recording of information is performed through the modulation of refractive index due to the cationic polymerization thereof, for instance, a compound which is incapable of absorbing the recording light and is capable of generating a base when exposed to an external stimulus is employed as a polymerization inhibitor. The polymerization inhibitor to be employed in this case may be formed of a compound which is incapable of absorbing the recording light and is selected from the aforementioned anionic photopolymerization initiators. When the recording layer formed of a photopolymer of this kind is heated after finishing the recording of information by laser, a base is generated from the polymerization inhibitor. Even in the case where a light having a wavelength which can be absorbed by a polymerization initiator of the same kind is irradiated to the recording layer, a base can be newly generated. In either cases, the cationic polymerization can be inhibited by the effects of the base that has been generated from the polymerization initiator.

When a base is generated from a polymerization initiator at a quantity which is almost equivalent to the unreacted cationic polymerization initiator contained in a photopolymer when the polymerization initiator is exposed to an external stimulus after the recording of information, it is possible to prevent the polymerization reaction from taking place in such a manner as to disturb the recording even if the cationic polymerizable monomer remains in the recording layer. Since the polymerization initiator is substantially incapable of absorbing the recording light, there is no possibility that the polymerization reaction of the monomer is obstructed during the recording.

In the case of the photopolymer which brings about the modulation of refractive index due to the anionic polymerization thereof, a compound which is incapable of absorbing the recording light and is capable of generating an acid when exposed to an external stimulus is employed as a polymerization inhibitor. The polymerization inhibitor to be employed in this case may be formed of a compound which is incapable of absorbing the recording light and is selected from the aforementioned cationic photopolymerization initiators.

In the case of the photopolymer which brings about the modulation of refractive index due to the cationic polymerization or anionic polymerization thereof, the effect thereof to inhibit the polymerization after the recording of information can be secured as long as a photopolymerization initiator is contained in the photopolymer at a quantity approximately equivalent to a polymerization inhibitor prior to the recording of information. With respect to the content of the polymerization inhibitor, it may be determined so as to make it equivalent at most to the photopolymerization initiator that is assumed to remain after the recording.

In the case of the photopolymer which brings about the modulation of refractive index due to the radical polymerization thereof, a compound which is incapable of absorbing the recording light and is capable of generating an acid or a base when exposed to an external stimulus is employed as a polymerization inhibitor. In this case, it is more preferable to additionally incorporate a latent radical polymerization inhibitor which generates a compound which is effective in inhibiting the radical polymerization when exposed to the acid or the base. By doing so, it is possible to shorten the time required for the fixing treatment to be performed through exposure after finishing the recording treatment and, at the same time, to minimize the voluminal contraction that may be caused by the exposure after the recording treatment.

As the latent radical polymerization inhibitor, it is possible to employ a compound formed of phenols or naphthols, wherein a hydroxyl group of phenol or naphthol is substituted by a protective group which can be eliminated when exposed to an acid or a base. Specific examples of phenols include, for example, 1,4-dihydroxy benzene, catechol, tert-butyl catechol, p-cresol, 2,5-dichloro-1,4-dihydroxy benzene, 2,6-dichloro-1,4-dihydroxy benzene, 2,3,5,6-tetrachloro-1,4-dihydroxy benzene, methyl-1,4-dihydroxy benzene, methoxy-1,4-dihydroxy benzene, 2,6-di-tert-butyl-4-methylphenol, 2,2′-methylene bis(6-tert-butyl-3-methylphenol), 4,4′-butylidene bis(1,6-tert-butyl-3-methylphenol), etc. Specific examples of naphthols include, for example, 1-naphthol, 2-naphthol, 4-naphthoxy-1-naphthol, etc.

Specific examples of the protective group which can be eliminated when exposed to an acid or a base include, for example, methyl, ethyl, n-propyl, iso-propyl, tert-butyl, n-butyl, iso-butyl, sec-butyl, trimethylsilyl, triethylsilyl, tert-butyldimethylsilyl, methoxymethyl, benzyl, 4-methoxyphenylmethyl, 2,4-dimethoxyphenylmethyl, 3,4-dimethoxyphenylmethyl, phenylethyl, 4-bromophenylethyl, benzoyl, 9-fluorenemethoxycarbonyl, tetrahydropyranyl, tetrahydrofuranyl, benzyloxycarbonyl, tert-buthoxycarbonyl, acetyl, tert-butylacetyl, 2-methyl-2-adamanthyl, 2-methyl-2-norbornyl, tetracyclodecyl, menthyl, diphenylethyl, etc.

Among these latent radical polymerization inhibitors, it is more preferable to employ phenol derivatives wherein a phenolic hydroxyl group thereof is substituted by a protective group which can be eliminated when exposed to an acid or a base. When these latent radical polymerization inhibitors are irradiated with light after the recording of information, the protective group thereof is eliminated by the effects of an acid or a base, thereby enabling the phenolic hydroxyl group to regenerate and, due to these phenols, the radical polymerization is inhibited. Further, since the acid and the base act as a catalyst, it is possible to regenerate phenols even if the quantity of the acid and base is very little. Due to these reasons, it is possible to obtain advantages that the time period needed for the irradiation of light after finishing the recording can be shortened as compared with that required in the prior art. Furthermore, in the embodiments, since all of the unreacted polymerizable compounds are not polymerized, it is possible to minimize the volume contraction of the recording layer and hence to accurately read out the recorded information.

In the case of the photopolymer wherein the refractive index thereof can be modulated by the radical polymerization thereof, the effect thereof to inhibit the polymerization after the recording of information can be secured as long as a photopolymerization initiator is contained in the photopolymer in a quantity approximately equivalent to a latent radical polymerization inhibitor prior to the recording of information. With respect to the content of the latent radical polymerization inhibitor, it may be determined so as to make it equivalent at most to the photopolymerization initiator that is assumed to remain after the recording. The quantity of the polymerization initiator may be 0.1 to 1 equivalent to the latent radical polymerization inhibitor.

If necessary, a sensitizing dye such as cyanine, merocyanine, xanthene, coumalin, eosin, etc., a silane coupling agent and a plasticizer may be incorporated in the raw material solution for the recording layer.

The optical recording medium according to one embodiment can be obtained by a process wherein a raw material solution for the recording layer, which contains the aforementioned components, is coated on the substrate to create the recording layer. With respect to the substrate, it is possible to employ a glass substrate or a transparent plastic substrate made of polycarbonate, cycloolefin polymer, etc. An inorganic film having a thickness of about 5 nm-100 nm and made of SiO₂, SiOC, SiOCN, etc. is preferably coated on the surface of the plastic substrate which is designed to be in contact with the recording layer. By doing so, it is possible to inhibit the deterioration of the substrate that may be caused by the acid or the base to be generated by the raw material solution for the recording layer or by the irradiation of light. Additionally, it is also possible to inhibit the oxygen in the external atmosphere from reaching the recording layer. If required, the aforementioned inorganic film may be coated on the other surface of the plastic substrate which may be in contact with air.

The coating of the recording layer can be performed by a casting method and a spin-coating method. A pair of glass substrates are disposed with a resin spacer interposed therebetween to create a space into which a precursor solution for the recording layer is poured, thereby forming the recording layer. As the film thickness of the recording layer, it should preferably be confined within the range of 20 μm to 5 mm. If the film thickness of the recording layer is less than 20 μm, it may become difficult to secure a sufficient quantity of memory. On the other hand, if the film thickness of the recording layer exceeds 5 mm, the transmissivity of the recording layer may be lowered, thus deteriorating the resolution of the recording layer. More preferably, the film thickness of the recording layer should be confined within the range of 50 μm to 2 mm.

On the occasion of performing the recording in the optical recording medium according to one embodiment, an information beam as well as reference beam is irradiated into the recording medium. By enabling these two beams to interfere in the interior of the recording layer, the recording or the regeneration of the hologram is performed. As the type of hologram (holography) to be recorded, it may be either a transmission type hologram (transmission type holography) or a reflection type hologram (reflection type holography). As the method of generating the interference between the information beam and the reference beam, it may be a two-beam interference method or a coaxial interference method.

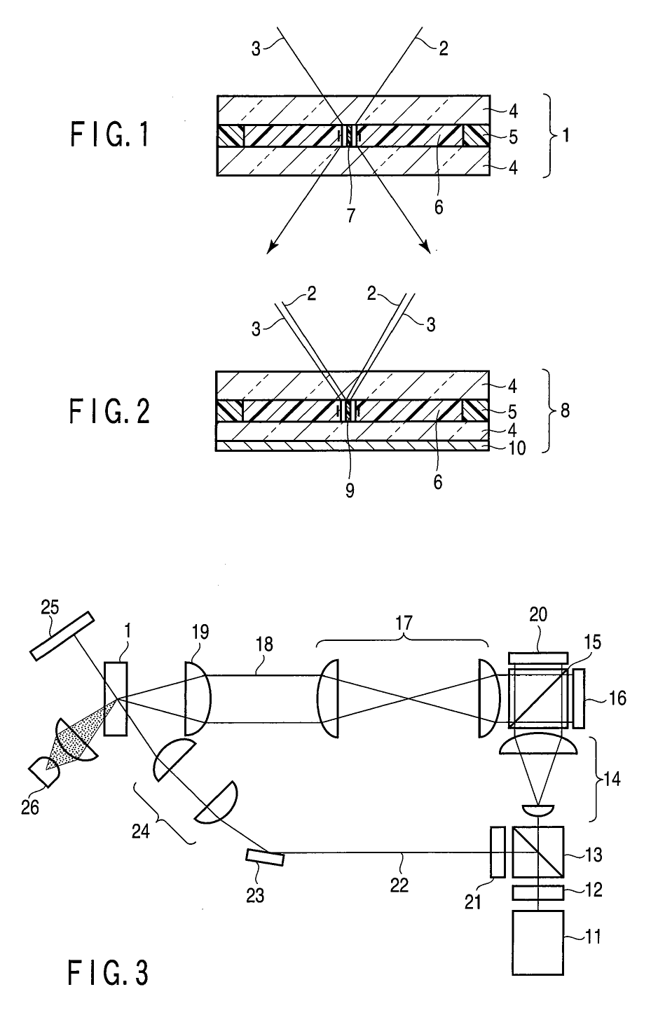

FIG. 1 shows a diagram schematically illustrating the transmission type holographic recording medium and also illustrating the information beam and the reference beam to be irradiated in the vicinity of the holographic recording medium. As shown in FIG. 1, the holographic recording medium 1 is composed of a pair of transparent substrates 4, between which a spacer 5 and a recording layer 6 are sandwiched. The transparent substrates 4 are respectively made of glass or a plastic such as polycarbonate. The recording layer 6 is formed of a polymer matrix containing, in addition to the polymerizable compound and the photopolymerization initiator described above, a compound (a polymerization inhibitor) which generates an acid or a base when exposed to an external stimulus and which exhibits a molar extinction coefficient of zero to the recording light.

As an information beam 2 and a reference beam 3 are irradiated into the holographic recording medium 1, these beams are intersected in the recording layer 6. As a result, interference is generated between these beams, thereby creating a transmission type hologram 7 in the modulated region.

The optical recording medium according to one embodiment can be used also as a reflection type holographic recording medium. In this case, the recording can be performed as shown in FIG. 2. FIG. 2 shows a diagram schematically illustrating a reflection type holographic recording medium and also illustrating the information beam and the reference beam to be irradiated in the vicinity of the holographic recording medium. As shown in FIG. 2, the holographic recording medium 8 includes a pair of transparent substrates 4 formed of glass or a plastic such as polycarbonate, a spacer 5 and a recording layer 6 which are sandwiched between the transparent substrates 4, and a reflection layer 10 supporting the substrates 4. As in the case of the transmission type holographic recording medium, the recording layer 6 is formed of a polymer matrix containing, in addition to the polymerizable compound and the photopolymerization initiator described above, a compound (a polymerization inhibitor) which generates an acid or a base when exposed to an external stimulus and which exhibits a molar extinction coefficient of zero to the recording light.

As in the case of the transmission type holographic recording medium, even in the case of this reflection type holographic recording medium 8, when an information beam 2 and a reference beam 3 are irradiated into the holographic recording medium 8, these beams are intersected in the recording layer 6. As a result, interference is generated between these beams, thereby creating a reflection type hologram 9 in the modulated region (not shown).

In the optical recording medium according to one embodiment, the fixing of information after the information has been recorded in the recording layer by the irradiation of recording light can be performed by application of an external stimulus, differing from the recording light, to the recording layer. Due to this external stimulus, which differs from the recording light, an acid or a base is generated from the compound that has been incorporated as a polymerization inhibitor in the polymer matrix, thereby making it possible to inhibit the polymerization of an unreacted polymerizable compound and hence to fix the information. As a result, the time required for the fixing treatment can be reduced and hence the contraction of the recording layer due to the fixing treatment can also be suppressed. Due to the suppression of the polymerization of the unreacted polymerizable compound, it is now possible to accurately read out, over a long period of time, the optically recorded information that has been recorded in the optical recording medium of the embodiment.

Next, the present invention will be further explained with reference to specific examples as follows.

### EXAMPLE 1

Using a photopolymer containing epoxy resin as a polymer matrix, a transmission type hologram recording medium as shown in FIG. 1 was manufactured. A series of operations were performed in a room where a light having a shorter wavelength than 600 nm was prevented from entering into the room, thereby preventing the recording layer from being exposed to the light. Examples to be described below were also performed under such conditions as described above.

First of all, 1.62 g of tetraethylene pentamine and 6.04 g of 1,6-hexanediol diglycidyl ether (epoxy equivalent:151; Nagase ChemteX Corporation) were mixed with each other to obtain a precursor of the matrix polymer.

Then, 1.352 g of N-vinyl carbazole as a radical polymerizable compound, 0.041 g of Irgacure 784 (Ciba Japan K.K.) as a radical photopolymerization initiator, 0.020 g of a compound represented by the following chemical formula (1) and 0.023 g of a compound represented by the following chemical formula (2) were mixed together to obtain a homogeneous solution. The solution thus obtained was employed as a recording layer precursor solution.

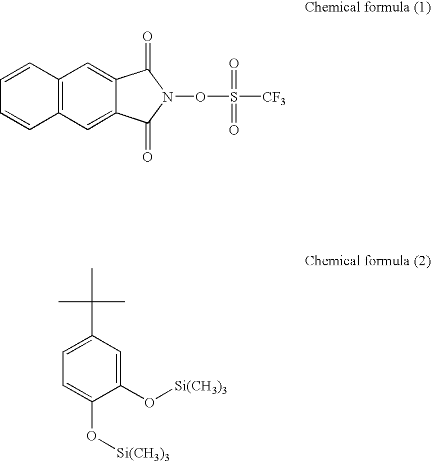

The compound represented by the chemical formula (1) is featured in that it exhibits a molar extinction coefficient of zero to the light having a wavelength of 390-600 nm and generates an acid when irradiated with the light having a wavelength of 210-370 nm. Namely, this compound is substantially incapable of absorbing the recording light in a case wherein the recording is performed irradiating the light having a wavelength of 390-600 nm and the fixing treatment is performed irradiating the light having a wavelength of 210-370 nm. Furthermore, this compound generates an acid when exposed to irradiation of the light having a different wavelength from that of the recording light, thus enabling the compound to act as a polymerization inhibitor. The compound represented by the chemical formula (2) is a latent polymerization inhibitor which generates a polymerization inhibitor when exposed to an acid.

In this example, a semiconductor laser exhibiting a wavelength of 405 nm was employed as the recording light and the fixing treatment was performed using a mercury lamp.

A pair of glass plates were employed respectively as a substrate 4 and superimposed with a spacer 5 formed of a 0.2 mm-thick Teflon (registered trademark) sheet being interposed therebetween to create a space. Then, the aforementioned precursor solution for a recording layer was poured into this space. The resultant structure was stored at room temperature (25° C.) for 4 days under a light-shielded condition, thereby manufacturing a holographic optical recording medium, as shown in FIG. 1.

For the assessment of the optical recording medium thus obtained, a holographic recording/reading apparatus shown in FIG. 3 was employed. The holographic recording/reading apparatus shown herein was an optical recording/reading apparatus employing double beam interferometry.

The beam irradiated from a light source device 11 is introduced, via an optical element for rotatory polarization 12, into a polarized beam splitter 13. As the light source device 11, a GaN type semiconductor laser provided with an external resonator was employed. This light source apparatus was designed to emit the light having a wavelength of 405 nm as a coherent beam. In view of coherence, it is possible to employ any desired linearly polarized laser. As the laser, it is possible to employ a semiconductor laser, a He—Ne laser, an argon laser and a YAG laser.

As the optical element 12 for rotatory polarization, a ½-wavelength plate for a wavelength of 405 nm was employed. The ½-wavelength plate was adjusted with respect to the bearing thereof so as to maximize the contrast of the hologram to be recorded in the transmission type recording medium 1.

The beam introduced into the polarized beam splitter 13 was split into two and one of them was introduced, via a beam expander 14, into another polarized beam splitter 15, thereby supplying information by a reflection type spatial light modulator 16. Further, the beam is permitted to pass through a relay lens 17 and irradiated, as an information beam 18, to the transmission type holographic recording medium 1 through an objective lens 19. As the reflection type spatial light modulator 16, a reflection type liquid crystal panel was employed.

Incidentally, the reference number 20 represents a two-dimensional light detector and a CCD array was employed herein as the two-dimensional light detector.

The other beam that had been split by the polarized beam splitter 13 was permitted to pass through an optical element for rotatory polarization 21, enabling the other beam to be used as a reference beam 22. With respect to the optical element for rotatory polarization 21, a ½-wavelength plate for a wavelength of 405 nm was employed. The ½-wavelength plate was adjusted with respect to the bearing thereof so as to make the direction of rotatory polarization of the information beam identical with that of the reference beam 22 at the transmission type optical recording medium 1. This reference beam 22 was irradiated, via a mirror 23 and a relay lens 24, to the transmission type optical recording medium 1.

In order to stabilize the hologram that has been recorded, light is irradiated from an ultraviolet source apparatus 26 after the recording of the hologram, thereby generating an acid or a base from the polymerization inhibitor. Alternatively, by the acid or the base that has been generated from this light exposure, a polymerization inhibitor may be created. The light to be irradiated from the ultraviolet source apparatus 26 may be optionally selected as long as the light can be absorbed by the polymerization inhibitor and an acid or a base can be generated from the polymerization inhibitor. Because of excellence in ultraviolet ray-emitting efficiency, it is preferable to employ, for example, a xenon lamp, a mercury lamp, a high-pressure mercury lamp, a mercury xenon lamp, a gallium nitride-based emission diode, a gallium nitride-based semiconductor laser, an excimer laser, a tertiary harmonics (355 nm) of Nd:YAG laser, and a quaternary harmonics (266 nm) of Nd:YAG laser.

On the occasion of performing the recording of information in the recording medium using the apparatus shown in FIG. 3, a transmission type hologram type optical recording medium is mounted on the optical recording/reading apparatus at first. The recording of information can be performed by an angular multiple recording method wherein the angle of incidence of the reference beam 22 was changed for every page by actuating the mirror 23. For example, the recording spot may be set to 3 mm in radius, to 0.5° in intervals of angle of the reference beam, and to 40 pages in multiplicity number per spot to create a regenerated image, which is then employed for assessing the recording properties thereof.

The intensity of light on the surface of the optical recording medium 1 was set, for example, to 0.5 mW and the exposure time per page was set to one second. Only the information beam region 49 as shown in FIG. 5 was displayed in the reflection type spatial light modulator 16. In this information beam region 49, a region constituted by 144 pixels×144 pixels (20736 pixels) was employed and the unit panel was formulated to include 16 pixels (4 pixels×4 pixels), thereby handling the information by employing 1296 panels in total. As the method of representing the information, there was employed a 16:3 modulation method wherein three pixels out of 16 pixels (4×4 pixels) was employed as a luminous pixel. Namely, it was possible to represent the information by 256 ways (one byte) per panel, thus securing 1296 bytes per page as the quantity of information. Then, in order to stabilize the recorded hologram, light was irradiated for one minute by the ultraviolet ray-irradiating apparatus 26.

The fixing exposure after the recording of information can be performed using any light source which irradiates a light having a wavelength that can be absorbed by the polymerization inhibitor. For example, it is possible to employ, a xenon lamp, a mercury lamp, a high-pressure mercury lamp, a mercury xenon lamp, a gallium nitride-based emission diode, a gallium nitride-based semiconductor laser, an excimer laser, a tertiary harmonics (355 nm) of Nd:YAG laser, and a quaternary harmonics (266 nm) of Nd:YAG laser.

The regeneration of the recorded hologram was performed by a CCD array 20. On the occasion of the regeneration, only the reference beam 22 was irradiated onto the optical recording medium 1 while rotating the optical element for rotatory polarization 12. The mirror 25 was adjusted so as to make the reference beam 22 reflect perpendicularly. The bearing of the optical element for rotatory polarization 12 was adjusted so as to maximize the intensity of reading light to be obtained at the CCD array 20. The intensity of light at the optical recording medium at the time of regeneration was set to 0.5 mW for instance.

The error ratio for a total of 51840 bytes of 40 pages was assessed by the aforementioned procedure. The hologram recording performance was assessed by M/# (M number), which represents a dynamic range of recording. This M/# can be defined by the following formula using ηᵢ. This ηᵢ represents a diffraction efficiency to be derived from i-th hologram as holograms of n pages are subjected to angular multiple recording/regeneration until the recording at the same region in the recording layer of the holographic recording medium becomes no longer possible. This angular multiple recording/regeneration can be performed by irradiating a predetermined beam to the holographic recording medium 1 while rotating the mirror 23.

$$M \text{/} \# = {\sum }_{i = 1}^{n} \sqrt{η} i \qquad Numerical Formula ( 1 )$$

Incidentally, the diffraction efficiency η was defined by the light intensity Iₜ detected at the beam detector 25 and the light intensity I_{d} detected at the beam detector 20 on the occasion when only the reference beam 22 was irradiated to the holographic recording medium 1. Namely, the diffraction efficiency p was defined by an inner diffraction efficiency which can be represented by η=I_{d}/(Iₜ+I_{d})

As the value of M/# of the holographic optical recording medium becomes larger, the dynamic range of recording is further enlarged, thus enabling to enhance the multiple recording performances.

The value of M/# of the holographic optical recording medium according to this example was 5.1. Referring to Applied Physics Letters, Volume 73, Number 10, pp 1337-1339 (1998), Lisa Dhar, Melinda G. Schnoes, Theres L. Wysocki, Harvey Bair, Mercia Shchilling Caril Boyd, the ratio of volume contraction was measured based on a difference in angle between the angle employed for the recording of information and the angle employed for the reading of information. As a result, the ratio of volume contraction was 0.22%. When the ratio of volume contraction is not more than 0.30%, it may be regarded that the contraction of volume contraction has not occurred to any substantial degree.

Then, the fixing treatment was performed by irradiating the light to the recording layer for one minute using the ultraviolet ray-irradiating apparatus 26, thereby enhancing the stability of the recorded hologram. When the ratio of volume contraction was measured in the same manner as described above, the ratio of volume contraction was 0.27%. The magnitude of increase in contraction ratio of the recording layer due to the fixing treatment was calculated as being 0.05%, thereby confirming that the increase in the contraction ratio could be suppressed to such a range that could be disregarded. Further, the error ratio at four spots that were recorded in the holographic optical recording medium 1 was 1/5184. The error ratio confined within the range of not more than about 10/5184 may be regarded being acceptable.

This recording medium was kept in a dark room at room temperature for two months and then the M/# and the error ratio at the recorded portions were measured. As a result, the M/# was 5.0 and the error ratio was 1/5184, both values being almost the same as those measured before the storage of the recording medium, thus confirming that the recording medium was not deteriorated in any substantial degree.

Further, the recording and regeneration of the recording medium of the same kind as described above was performed by following the same procedures as described above except that the fixing treatment time by the ultraviolet ray-irradiating apparatus 26 was changed to one hour. As a result, the ratio of volume contraction was 0.28% and the error ratio was 2/5184, thus indicating a small difference as compared with the case where the fixing treatment was performed by the irradiation of light for one minute. In view of this, it will be recognized that the time required for the fixing treatment can be reduced.

### COMPARATIVE EXAMPLE 1

A holographic recording medium was manufactured by following the same procedures as described in Example 1 and by the same recording layer precursor solution as employed in Example 1 except that the polymerization inhibitor as well as the latent polymerization inhibitor was not incorporated in the solution.

Then, the recording medium obtained was measured with respect to the M/# and the ratio of volume contraction in the same manner as employed in Example 1. As a result, the M/# was 5.2 and the ratio of volume contraction was 0.22%. Then, the fixing treatment was performed by irradiating the light to the recording layer for one minute by the ultraviolet ray-irradiating apparatus 26, thereby enhancing the stability of the recorded hologram. The ratio of volume contraction after the fixing treatment was 0.27% and the error ratio was 2/5184.

This recording medium was kept in a dark room at room temperature for two months and then the M/# and the error ratio at the recorded portions were measured. As a result, the M/# was 3.8 and the error ratio was 48/5184, both values indicating high deterioration as compared with those measured before the storage of the recording medium. It will be recognized that the recording medium obtained herein was much poorer in performance as compared with the recording medium of Example 1, which was almost free from deterioration.

Further, the recording and regeneration of the recording medium of the same kind as described above was performed by following the same procedures as described above except that the fixing treatment time by the ultraviolet ray-irradiating apparatus 26 was changed to one hour. As a result, the ratio of volume contraction was 0.60% and the error ratio was 89/5184, thus indicating prominent increases of values as compared with those of Example 1.

In Example 1, the compound represented by the chemical formula (1) was enabled to generate an acid as the compound was exposed to fixing exposure and, further, due to this acid, the compound represented by the chemical formula (2) was decomposed to generate phenol. These reactions proceeded effectively even if the time period of exposure was relatively short, and, due to the phenol generated in this manner, it was possible to suppress the polymerization of the unreacted radical polymerizable monomer. Since this effect was sustainable for a long period of time, no substantial increase in the error ratio or increase in the ratio of volume contraction was recognized even if the recording medium was left to stand for two months.

On the other hand, in the case of Comparative Example 1 wherein the polymerization inhibitor was not employed, unreacted monomer was present when the fixing exposure was performed for a relatively short period of time. As a result, the reaction of the unreacted monomer was caused to take place gradually with time, thereby increasing the error ratio. Further, when the reaction of the unreacted monomer was completely accomplished by performing a long period of exposure, the ratio of volume contraction was caused to increase and, at the same time, the error ratio was also caused to increase.

### EXAMPLE 2

First of all, 1.62 g of tetraethylene pentamine and 6.04 g of 1,6-hexanediol diglycidyl ether (epoxy equivalent:151; Nagase ChemteX Corporation) were mixed with each other to obtain a precursor of the matrix polymer.

Then, 0.577 g of 2-vinyl naphthalene as a radical polymerizable compound, 0.033 g of Irgacure 784 (Ciba Japan K.K.) as a radical photopolymerization initiator, 0.020 g of a compound represented by the following chemical formula (3) and 0.023 g of a compound represented by the following chemical formula (4) were mixed together to obtain a homogeneous solution. The solution thus obtained was employed as a recording layer precursor solution.

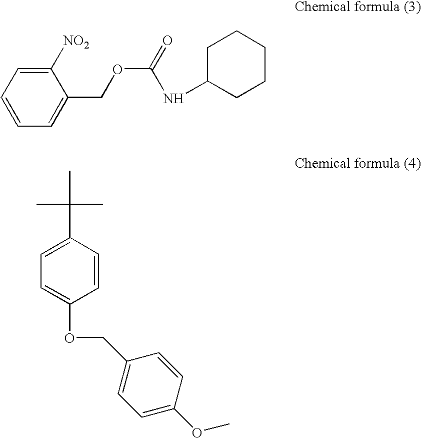

The compound represented by the chemical formula (3) is featured in that it exhibited a molar extinction coefficient of zero to the light having a wavelength of 390-600 nm and generates a base when irradiated with the light having a wavelength of 210-370 nm. Namely, this compound is substantially incapable of absorbing the recording light in a case wherein the recording is performed irradiating the light having a wavelength of 390-600 nm and the fixing treatment is performed irradiating the light having a wavelength of 210-370 nm. Furthermore, this compound generates a base when exposed to the irradiation of the light having a different wavelength from that of the recording light, thus enabling the compound as a polymerization inhibitor. The compound represented by the chemical formula (4) is a latent polymerization inhibitor which generates a polymerization inhibitor when exposed to an acid.

In this example, a semiconductor laser exhibiting a wavelength of 405 nm was employed as the recording light and the fixing treatment was performed using a mercury lamp.

Using this recording layer precursor solution, a holographic recording medium was manufactured by following the same procedures as described in Example 1.

Then, the recording medium obtained was measured with respect to the M/# and the ratio of volume contraction in the same manner as employed in Example 1. As a result, the M/# was 6.8 and the ratio of volume contraction was 0.21%. Then, the fixing treatment was performed by irradiating the light to the recording layer for one minute by the ultraviolet ray-irradiating apparatus 26, thereby enhancing the stability of the recorded hologram. The ratio of volume contraction after the fixing treatment was 0.24% and the increase in ratio of volume contraction was 0.03%. As explained above, when the ratio of volume contraction and the increase in ratio of volume contraction are confined to these values, they are considered as being acceptable. Further, the error ratio was 2/5184.

This recording medium was kept in a dark room at room temperature for two months and then the M/# and the error ratio at the recorded portions were measured. As a result, the M/# was 6.6 and the error ratio was 3/5184, both values indicating almost the same as those measured before the storage of the recording medium, thus confirming the generation of almost no deterioration.

Further, the recording and regeneration of the recording medium of the same kind as described above was performed by following the same procedures as described above except that the fixing treatment time by the ultraviolet ray-irradiating apparatus 26 was changed to one hour. As a result, the ratio of volume contraction was 0.25% and the error ratio was 3/5184, thus indicating a small difference as compared with the case where the fixing treatment was performed by the irradiation of light for one minute. In view of this, it will be recognized that the time required for the fixing treatment can be reduced.

### COMPARATIVE EXAMPLE 2

A holographic recording medium was manufactured by following the same procedures as described in Example 2 and by the same recording layer precursor solution as employed in Example 2 except that the polymerization inhibitor and the latent polymerization inhibitor were not incorporated in the solution.

Then, the recording medium obtained was measured with respect to the M/# and the ratio of volume contraction in the same manner as employed in Example 1. As a result, the M/# was 6.8 and the ratio of volume contraction was 0.21%. Then, the fixing treatment was performed by irradiating the light to the recording layer for one minute by the ultraviolet ray-irradiating apparatus 26, thereby enhancing the stability of the recorded hologram. The ratio of volume contraction after the fixing treatment was 0.25% and the error ratio was 4/5184.

This recording medium was kept in a dark room at room temperature for two months and then the M/# and the error ratio at the recorded portions were measured. As a result, the M/# was 4.2 and the error ratio was 88/5184, both values indicating high deterioration as compared with those measured before the storage of the recording medium. It will be recognized that the recording medium obtained herein was much poorer in performance as compared with the recording medium of Example 2 which was almost free from deterioration.

Further, the recording and regeneration of the recording medium of the same kind as described above was performed by following the same procedures as described above except that the fixing treatment time by the ultraviolet ray-irradiating apparatus 26 was changed to one hour. As a result, the ratio of volume contraction was 0.66% and the error ratio was 101/5184, thus indicating prominent increases of values as compared with those of Example 2.

In Example 2, the compound represented by the chemical formula (3) was enabled to generate a base as the compound was exposed to fixing exposure and, further, due to this base, the compound represented by the chemical formula (4) was decomposed to generate phenol. These reactions proceeded effectively even if the time period of exposure was relatively short, and due to the phenol generated in this manner, the polymerization of the unreacted radical polymerizable monomer can be suppressed. Since this effect was sustainable for a long period of time, no substantial increase in the error ratio and no substantial increase in the ratio of volume contraction were recognized even if the recording medium was left to stand for two months.

On the other hand, in the case of Comparative Example 2 wherein the polymerization inhibitor was not employed, unreacted monomer left when the fixing exposure was performed for a relatively short period of time. As a result, the reaction of the unreacted monomer was caused to take place gradually with time, thereby increasing the error ratio. Further, when the reaction of the unreacted monomer was completely accomplished by performing a long period of exposure, the ratio of volume contraction was caused to increase, and, at the same time, the error ratio was also caused to increase.

### EXAMPLE 3

First of all, 5.0 g of 1,6-hexanediol diglycidyl ether (epoxy equivalent:151; Nagase ChemteX Corporation.) and 0.4 g of aluminum tris(ethylacetyl acetate) as a metal complex were mixed with each other in a dark room to obtain a mixture. Then, this mixture was heated at 60° C. with stirring to prepare a metal complex solution.

Further, 5.0 g of 1,6-hexanediol diglycidyl ether (epoxy equivalent:151; Nagase ChemteX corporation.) and 0.6 g of triphenyl silanol representing alkyl silanol were mixed with each other to obtain a mixture. Then, this mixture was heated at 60° C. with stirring to obtain a silanol solution.

Then, the metal complex solution and the silanol solution were mixed together and stirred to obtain a mixed solution. 5 g of this mixed solution was taken up and mixed with 0.89 g of a cationic polymerizable compound and 0.10 g of a cationic photopolymerization initiator. As the cationic polymerizable compound, phenyl oxetane represented by the following chemical formula (5) was employed. As the cationic photopolymerization initiator, an iodonium salt represented by the following chemical formula (6) was employed.

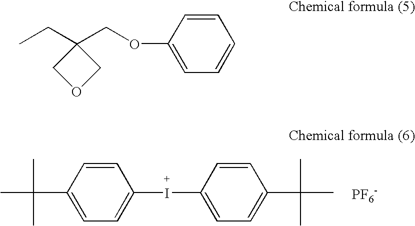

Further, 0.008 g of 2-isopropyl thioxanthen-9-one as a sensitizing agent and 0.020 g of a compound represented by the chemical formula (3) were added to and mixed with the aforementioned mixed solution to obtain a homogeneous solution. As described above, the compound represented by the chemical formula (3) acts as a polymerization inhibitor in a case wherein the recording is performed irradiating the light having a wavelength of 390-600 nm and the fixing treatment is performed irradiating the light having a wavelength of 210-370 nm. Finally, the resultant solution was deaerated to obtain a raw material solution for the recording layer.

In this example, a semiconductor laser exhibiting a wavelength of 405 nm was employed as a recording beam and a mercury lamp was employed for performing the fixing treatment.

A pair of glass plates were employed respectively as a substrate 4 and superimposed with a spacer 5 formed of a Teflon (registered trademark) sheet being interposed therebetween to create a space. Then, the aforementioned raw material solution for a recording layer was poured into this space. The resultant structure was heated for 24 hours in an oven heated at 55° C. under a light-shielded condition, thereby manufacturing a test piece of a holographic recording medium provided with a recording layer having a thickness of 200 μm.

Then, the recording medium obtained was measured with respect to the M/# and the ratio of volume contraction in the same manner as employed in Example 1. As a result, the M/# was 5.4 and the ratio of volume contraction was 0.26%. Then, the fixing treatment was performed by irradiating the light to the recording layer for one minute by the ultraviolet ray-irradiating apparatus 26, thereby enhancing the stability of the recorded hologram. The ratio of volume contraction after the fixing treatment was 0.27% and the increase in ratio of volume contraction was 0.02%. As explained above, when the ratio of volume contraction and the increase in ratio of volume contraction are confined to these values, they are considered as being acceptable. Further, the error ratio was 2/5184.

This recording medium was kept in a dark room at room temperature for two months and then the M/# and the error ratio at the recorded portions were measured. As a result, the M/# was 5.3 and the error ratio was 3/5184, both values indicating almost the same as those measured before the storage of the recording medium, thus confirming the generation of almost no deterioration.

Further, the recording and regeneration of the recording medium of the same kind as described above was performed by following the same procedures as described above except that the fixing treatment time by the ultraviolet ray-irradiating apparatus 26 was changed to one hour. As a result, the ratio of volume contraction was 0.29%, thus indicating a small difference as compared with the case where the fixing treatment was performed by the irradiation of light for one minute. In view of this, it will be recognized that the time required for the fixing treatment can be reduced.

### COMPARATIVE EXAMPLE 3

A holographic recording medium was manufactured by following the same procedures as described in Example 3 and by the same recording layer precursor solution as employed in Example 3 except that the polymerization inhibitor was not incorporated in the solution.

Then, the recording medium obtained was measured with respect to the M/# and the ratio of volume contraction in the same manner as employed in Example 1. As a result, the M/# was 5.3 and the ratio of volume contraction was 0.27%. Then, the fixing treatment was performed by irradiating the light to the recording layer for one minute by the ultraviolet ray-irradiating apparatus 26, thereby enhancing the stability of the recorded hologram. The ratio of volume contraction after the fixing treatment was 0.30% and the error ratio was 2/5184.

This recording medium was kept in a dark room at room temperature for two months and then the M/# and the error ratio at the recorded portions were measured. As a result, the M/# was 3.8 and the error ratio was 79/5184, both values indicating high deterioration as compared with those measured before the storage of the recording medium. Thus, it will be recognized that the recording medium obtained herein was much poorer in performance as compared with the recording medium of Example 3 which was almost free from deterioration.

Further, the recording and regeneration of the recording medium of the same kind as described above was performed by following the same procedures as described above except that the fixing treatment time by the ultraviolet ray-irradiating apparatus 26 was changed to one and a half hours. As a result, the ratio of volume contraction was 0.60% and the error ratio was 54/5184, thus indicating prominent increases of values as compared with those of Example 3.

In Example 3, the compound represented by the chemical formula (3) was enabled to generate a base as the compound was exposed to fixing exposure, thereby making it possible to suppress the polymerization of the unreacted radical polymerizable monomer. Since this effect was sustainable for a long period of time, no substantial increase in the error ratio and no substantial increase in the ratio of volume contraction was recognized even if the recording medium was left to stand for two months.

On the other hand, in the case of Comparative Example 3 wherein the polymerization inhibitor was not employed, unreacted monomer was permitted to exist when the fixing exposure was performed for a relatively short period of time. As a result, the reaction of the unreacted monomer was caused to take place gradually with time, thereby increasing the error ratio. Further, when the reaction of the unreacted monomer was completely accomplished by performing a long period of exposure, the ratio of volume contraction was caused to increase, and, at the same time, the error ratio was also caused to increase.

### EXAMPLE 4

Using a photopolymer containing epoxy resin as a polymer matrix, a reflection type hologram recording medium as shown in FIG. 2 was manufactured.

First of all, 1.62 g of tetraethylene pentamine and 6.04 g of 1,6-hexanediol diglycidyl ether (epoxy equivalent:151; Nagase ChemteX Corporaiton) were mixed with each other to obtain a precursor of the matrix polymer.

Then, 0.40 g of 2-vinyl naphthalene as a radical polymerizable compound, 0.032 g of Irgacure 784 (Ciba Japan K.K.) as a radical photopolymerization initiator, 0.016 g of a compound represented by the chemical formula (6) and 0.023 g of a compound represented by the following chemical formula (7) were mixed together to obtain a homogeneous solution. The solution thus obtained was employed as a recording layer precursor solution.

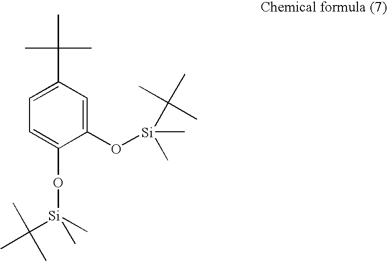

Incidentally, in the above Example 3, since a sensitizing agent was incorporated in the precursor solution, the iodonium salt represented by the chemical formula (6) was enabled to act as a cationic photopolymerization initiator. In this example however, since a sensitizing agent was not incorporated in the raw material solution, the iodonium salt represented by the chemical formula (6) was enabled to act as a polymerization initiator. Further, the compound represented by the chemical formula (7) is a latent polymerization inhibitor which generates a polymerization inhibitor when exposed to an acid.

A pair of glass plates were employed respectively as a substrate 4 and superimposed with a spacer 5 formed of a 0.2 mm-thick Teflon (registered trademark) sheet being interposed therebetween to create a space. Incidentally, one of the glass substrates was preliminarily vapor-deposited with an aluminum film acting as a reflection layer 10. Then, the aforementioned precursor solution for a recording layer was poured into this space. The resultant structure was stored at room temperature (25° C.) for 4 days under a light-shielded condition, thereby manufacturing a holographic photorecording medium as shown in FIG. 2.

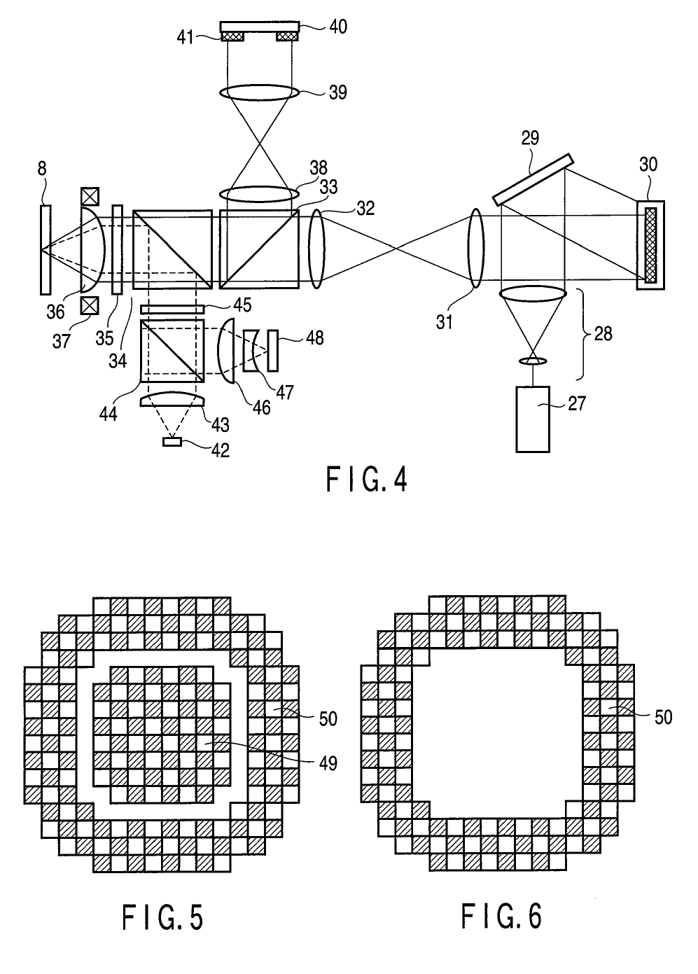

For the assessment of the optical recording medium thus obtained, a holographic recording/reading apparatus shown in FIG. 4 was employed. In this apparatus, the beam irradiated from a light source device 27 is introduced, via a beam expander 28 and a mirror 29, into a reflection type special modulator 30. As the light source device 27, a GaN type semiconductor laser provided with an external resonator was employed. This light source apparatus 27 was designed to emit the light having a wavelength of 405 nm as a coherent beam.

As the reflection type special modulator 30, a digital micromirror device was employed. The light modulated is introduced, via relay lens 31 and 32, into a polarization beam splitter 33. Thereafter, this modulated light is irradiated, via a dichroic lens 34, a rotatory polarization optical element 35 and an objective lens 36, to a holographic recording medium 8. As the rotatory polarization optical element 35, a ¼-wavelength plate for a wavelength of 405 nm was employed. This ¼-wavelength the plate was adjusted with respect to the bearing thereof so as to maximize the intensity of the reading beam on the surface of a two-dimensional beam detector 40.

A voice coil motor 38, an imaging lens 39, an iris 41 and two-dimensional beam detector 40 were successively disposed adjacent to the polarization beam splitter 33. As the two-dimensional beam detector 40, a CCD array was employed.

With respect to a servo light source apparatus 42, a semiconductor laser (wavelength: 650 nm) which was linearly polarized was used. The light that was emitted from the light source apparatus 42 is introduced, via a collimator lens 43, a polarization beam splitter 44 and a rotatory polarization optical element 45, into the dichroic lens 34. As the rotatory polarization optical element 45, a ¼-wavelength plate for a wavelength of 650 nm was employed. Even with this rotatory polarization optical element 45, the bearing thereof was adjusted so as to maximize the beam intensity on the surface of a four-sectioned photodetector 48. The light can be introduced, via a convex lens 46 and a cylindrical lens 47, into the four-sectioned photodetector 48.

Using the apparatus shown in FIG. 4, the recording of information to the recording medium was performed while actuating a servo mechanism. The recording was performed using a track having a radius of 24 mm, 36 mm or 48 mm. In each track, the recording of 4 spots separated by 90° intervals, i.e. the recording of 12 spots all over the optical recording medium was performed. The recording was performed under the conditions of: 0.1 mW in optical intensity on the surface of the holographic optical recording medium; 0.1 second in exposure time; and about 400 μm in diameter of the spot size of the laser beam on the top surface of recording layer. A modulation pattern as shown in FIG. 5 was displayed in the reflection type special modulator 30, thus enabling a central portion of the optical axis to be used as an information light region 49 and a peripheral portion of the optical axis to be used as a reference light region 50.

In this reflection type special modulator 30, a region constituted by 400 pixels×400 pixels (160000 pixels in total) was employed, in which a central region constituted by 144 pixels×144 pixels (20736 pixels in total) was employed as an information region. In this information region, the unit panel was formulated to include 16 pixels (4 pixels×4 pixels), thereby handling the information by employing 1296 panels in total. As the method of representing the information, there was employed a 16:3 modulation method wherein three pixels out of 16 pixels (4×4 pixels) was employed as a luminous pixel. Namely, it was possible to represent the information by 256 ways (one byte) per panel, thus securing 1296 bytes per page as the quantity of information. After finishing the recording, the recording medium 8 was removed from the recording apparatus and the irradiation of light to the entire body of the recording medium was performed for 30 seconds by an ultraviolet ray-irradiating apparatus, thereby fixing the recording.

The recording medium 8 having the information recorded therein was mounted on the optical recording/reading apparatus of FIG. 4 and aligned in position, after which the regeneration of a hologram was performed by a two-dimensional beam detector 40. On the occasion of the regeneration, only the reference light region 50 as shown in FIG. 6 was displayed on the reflection type special modulator, thereby utilizing it as a reference light. The optical intensity at the surface of the recording medium 8 was set to 0.01 mW.

Then, the recording/reading performance of the aforementioned optical recording medium was assessed on the basis of the error ratio by the following method. By the two-dimensional beam detector 40, over-sampling was performed wherein the light from one pixel at the reflection type special modulator 30 was received as 3×3 pixels.

The assessment of the error ratio was performed as follows. Namely, a region constituted by 432 pixels×432 pixels located in the information region was cut out on the two-dimensional beam detector 40 and the re-sampling thereof was performed by picture processing, thereby making it into a size of 144 pixels×144 pixels. Thereafter, three pixels exhibiting higher luminance among the unit panel of 4×4 pixels were selected as a luminous pixel, thereby determining a regeneration pattern. Finally, this regeneration pattern was compared with the pattern that had been input in the reflection type special modulator 30 to assess the recording/reading performance of the recording medium. As a result, the error ratio at the four spots recorded in the holographic optical recording medium 1 was 1/5184.

This recording medium was kept under a light-shielded condition at room temperature for two months and then the error ratio was measured again by the same method as described above. As a result, the error ratio was 3/5184, indicating almost the same as that measured before the storage of the recording medium, thus confirming the generation of almost no deterioration.

### COMPARATIVE EXAMPLE 4

A holographic recording medium was manufactured by following the same procedures as described in Example 4 and by the same recording layer precursor solution as employed in Example 4 except that the polymerization inhibitor as well as the latent polymerization inhibitor was not incorporated in the solution.

Then, the recording medium obtained was measured with respect to the error ratio of recording/reading. As a result, the error ratio was 1/5184. Then, this recording medium was kept under a light-shielded condition at room temperature for two months and then the error ratio was measured again by the same method as described above. As a result, the error ratio was 78/5184, thus indicating a prominent increase in deterioration as compared with that before the storage. In view of this fact, the recording medium of Comparative Example 4 was very low in performance as compared with the recording medium of Example 4 where almost no deterioration was recognized.

In Example 4, the compound represented by the chemical formula (6) was enabled to generate an acid as the compound was exposed to fixing exposure and, further, due to this acid, the compound represented by the chemical formula (7) was decomposed to generate phenol. These reactions proceeded effectively even if the time period of exposure was relatively short, and due to the phenol generated in this manner, it was possible to suppress the polymerization of the unreacted radical polymerizable monomer. Since this effect was sustainable for a long period of time, no substantial increase in the error ratio or the ratio of volume contraction was recognized even if the recording medium was left to stand for two months.

On the other hand, in the case of Comparative Example 4 wherein the polymerization inhibitor was not employed, unreacted monomer was permitted exist when the fixing exposure was performed for a relatively short period of time. As a result, the reaction of the unreacted monomer was caused to take place gradually with time, thereby increasing the error ratio. Further, when the reaction of the unreacted monomer was completely accomplished by performing a long period of exposure, the error ratio was also caused to increase.

### EXAMPLE 5

A pair of polycarbonate plates each having a thickness of 0.6 mm were prepared respectively as a substrate 4 and superimposed with a spacer 5 formed of a 0.2 mm-thick Teflon (registered trademark) sheet being interposed therebetween to create a space. By sputtering, an SiOC film having a thickness of 50 nm was coated on one of the surfaces of each of this pair of substrate, which was designed to be in contact with the recording layer. Further, an aluminum film was preliminarily vapor-deposited as a reflective layer 10 on the surface of one of the polycarbonate plates.

Then, the precursor solution for a recording layer which was obtained in Example 4 was poured into this space formed between the pair of substrates. The resultant structure was stored at room temperature (25° C.) for 4 days under a light-shielded condition, thereby manufacturing a holographic optical recording medium as shown in FIG. 2. When this optical recording medium was evaluated with respect to the error ratio by following the same method as described above, the error ratio at four spots recorded in the holographic optical recording medium was 2/5184.

This recording medium was kept under a light-shielded condition at room temperature for two months and then the error ratio was measured again by the same method as described above. As a result, the error ratio was 3/5184, indicating almost the same as that measured before the storage of the recording medium, thus confirming the generation of almost no deterioration.

In Example 5, in the same manner as in Example 4, the compound represented by the chemical formula (6) was enabled to generate an acid as the compound was exposed to fixing exposure and, further, due to this acid, the compound represented by the chemical formula (7) was decomposed to generate phenol. These reactions proceeded effectively even if the time period of exposure was relatively short, and due to the phenol generated in this manner, it was possible to suppress the polymerization of the unreacted radical polymerizable monomer. Since this effect was sustainable for a long period of time, no substantial increase in the error ratio was recognized even if the recording medium was left to stand for two months.

### EXAMPLE 6

5.0 g of 1,6-hexanediol diglycidyl ether (epoxy equivalent:151; Nagase ChemteX Corporation) and 0.4 g of aluminum tris(ethylacetyl acetate) as a metal complex were mixed with each other in a dark room to obtain a mixture. Then, this mixture was heated at 60° C. with stirring to prepare a metal complex solution.

Further, 5.0 g of 1,6-hexanediol diglycidyl ether (epoxy equivalent:151; Nagase ChemteX Corporation) and 0.6 g of triphenyl silanol representing alkyl silanol were mixed with each other to obtain a mixture. Then, this mixture was heated at 60° C. with stirring to obtain a silanol solution. Then, the metal complex solution and the silanol solution were mixed together and stirred to obtain a mixed solution. 5 g of this mixed solution was taken up and mixed with 0.89 g of naphthyl acrylate as a cationic polymerizable compound and 0.10 g of the compound represented by the aforementioned chemical formula (3).

In this example, the compound represented by the aforementioned chemical formula (3) was enabled to act as an anionic photopolymerization initiator. Further, 0.006 g of a compound represented by the following chemical formula (8) as a sensitizing agent and 0.020 g of a compound represented by the following chemical formula (9) were added to and mixed with the aforementioned mixed solution to obtain a homogeneous solution. The compound represented by the chemical formula (9) is featured in that it exhibits a molar extinction coefficient of zero to the light having a wavelength of 390-600 nm and generates an acid when exposed to heat. Namely, this compound acts as a thermal acid generating agent which is substantially incapable of absorbing the recording light in a case wherein the fixing treatment is performed by heating. Finally, the resultant solution was deaerated to obtain a precursor solution for the recording layer.

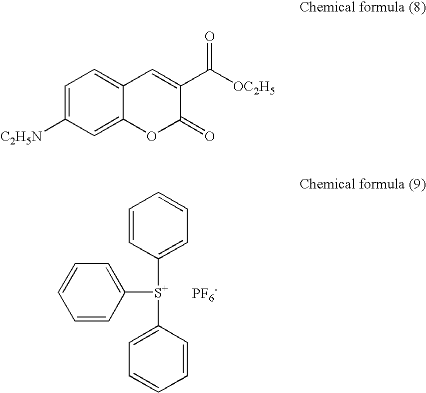

In this example, a semiconductor laser exhibiting a wavelength of 405 nm was employed as a recording beam and the fixing treatment was performed by heating.

The recording of information was performed by following the same procedures as described in Example 4, the recording medium was heated for 30 minutes in an oven heated to a temperature of 70° C. Then, the evaluation of the recording medium was conducted in the same manner as described in Example 4. As a result, the error ratio at four spots recorded in the holographic optical recording medium 1 was 5/5184.

This recording medium was kept under a light-shielded condition at room temperature for two months and then the error ratio was measured again by the same method as described above. As a result, the error ratio was 9/5184, indicating almost the same as that measured before the storage of the recording medium, thus confirming the generation of almost no deterioration.

In Example 6, the compound represented by the chemical formula (9) was enabled to generate an acid as the compound was exposed to fixing heating, thereby making it possible to suppress the polymerization of the unreacted anionic polymerizable monomer. Since this effect was sustainable for a long period of time, no substantial increase in the error ratio was recognized even if the recording medium was left to stand for two months.

According to the embodiment of the present invention, it is possible to provide an optical recording medium which is capable of minimizing the fixing treatment time after the recording process, thereby making it possible to suppress the contraction of the recording layer in the fixing treatment and to accurately read out the recorded information for a long period of time.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An optical recording medium comprising: a recording layer comprising a polymer matrix, a polymerizable compound, a photopolymerization initiator, and a polymerization inhibitor, the polymerization inhibitor being formed of a compound which exhibits a molar absorption coefficient of zero to a light having a first wavelength and generates an acid or a base when exposed to an external stimulus other than the light having the first wavelength.

2. The medium according to claim 1, wherein the recording layer further comprises a latent polymerization inhibitor which generates a polymerization inhibitor when exposed to an acid or a base.

3. The medium according to claim 1, wherein the external stimulus is selected from heat and a light having a second wavelength.

4. The medium according to claim 2, wherein the latent polymerization inhibitor is a latent radical polymerization inhibitor.

5. The medium according to claim 4, wherein the latent radical polymerization inhibitor is formed of phenol derivatives wherein a hydroxyl group of phenol is substituted by a protective group which can be eliminated when exposed to an acid or a base.

6. The medium according to claim 1, further comprising a pair of substrates sandwiching the recording layer, and an inorganic film interposed between the substrate and the recording layer.

7. The medium according to claim 1, wherein the polymer matrix is selected from the group consisting of thermoplastic resins, epoxy resin and urethane resin.

8. The medium according to claim 1, wherein the polymerizable compound is selected from the group consisting of a radical polymerizable monomer, a cationic polymerizable monomer, and an anionic polymerizable monomer.

9. The medium according to claim 1, wherein the polymerizable compound is incorporated at an amount of 1-50% by weight based on a total weight of the recording layer.

10. The medium according to claim 1, wherein the photopolymerization initiator is selected from the group consisting of a radical photopolymerization initiator, a cationic photopolymerization initiator, and an anionic photopolymerization initiator.

11. The medium according to claim 1, wherein the photopolymerization initiator is incorporated at an amount of 0.05-20% by weight based on a total weight of the recording layer.

12. The medium according to claim 1, wherein the polymerization inhibitor is formed of a compound which generates an acid when exposed to heat.

13. The medium according to claim 12, wherein the polymerization inhibitor is selected from the group consisting of a Lewis acid containing any one of materials including BF₃, SnCl₄, TiCl₄, AlEtCl₂, ZnCl₂, FeCl₃ and AlCl₃; diazonium salts; phosphonium salts; sulfonium salts; and iodonium salts.

14. The medium according to claim 1, wherein the polymerization inhibitor is formed of a compound which generates a base when exposed to heat.

15. The medium according to claim 13, wherein the polymerization inhibitor is selected from the group consisting of nitrobenzyl carbamate compounds and photo-functional urethane compounds.

16. The medium according to claim 1, wherein the recording layer has a thickness of 20 μm to 5 mm.

17. A method for optical recording, which comprises:
irradiating a first light having a first wavelength which can be absorbed by the photopolymerization initiator to the optical recording medium set forth in claim 1; and
applying an external stimulus to the optical recording medium having information recorded therein, the stimulus being heat or a second light having a second wavelength which differs in wavelength from the first wavelength and which can be absorbed by the photopolymerization initiator.

18. The method according to claim 17, wherein the first wavelength is confined to 390 nm-600 nm and the second wavelength is confined to 210 nm-370 nm.

19. The method according to claim 17, further comprising irradiating ultraviolet rays to the optical recording medium that has been irradiated with the second light.

20. An information recording/reading apparatus comprising: a light source; an optical element for rotatory polarization; a beam splitter; a mirror; and a detector; the apparatus is designed to read out and regenerate information from recorded portions of the optical recording medium set forth in claim 1.
